(19) United States
(12) Patent Application Publication
(10) Pub. No.: US 2025/0160025 A1
(43) Pub. Date: May 15, 2025

(54) IMAGE SENSOR

(71) Applicant: Commissariat à I'Énergie Atomique et aux Énergies Alternatives, Paris (FR)

(72) Inventors: François Ayel, Grenoble (FR); Olivier Saxod, Grenoble (FR); Cédric Giroud-Garampon, Grenoble (FR)

(73) Assignee: Commissariat à I'Énergie Atomique et aux Énergies Alternatives, Paris (FR)

(21) Appl. No.: 18/722,522

(22) PCT Filed: Dec. 15, 2022
(86) PCT No.: PCT/EP2022/086191

§ 371 Date: Jun. 20, 2024

(30) Foreign Application Priority Data
Dec. 23, 2021 (FR) FR2114336

(51) Int. Cl. H10F 39/00

(52) U.S. Cl. CPC H10F 39/807; H10F 39/8033

(57) ABSTRACT

An image sensor including a plurality of pixels formed in and on a semiconductor substrate, each pixel including: at least one first photosensitive region formed in the substrate; a second photosensitive region formed in the substrate in line with said at least one first photosensitive region; at least one charge collection area disposed on the side of the substrate opposite to said at least one first photosensitive area; at least one transfer region extending from said at least one first photosensitive area to said at least one charge collection area; and at least one vertical transfer gate laterally bordering said at least one transfer region.

The present application is based on, and claims the priority of, French patent application no 2114336 filed on Dec. 23, 2021 and entitled “Capteur d'images”, which is considered an integral part of the present description to the extent provided by law.

### TECHNICAL FIELD

The present description relates generally to the field of image acquisition devices. The present description relates more particularly to image acquisition devices adapted to acquire a 2D image and a depth image of a scene.

### BACKGROUND ART

Image acquisition devices capable of acquiring a 2D image and a depth image of a scene are known. In particular, devices with 2D image sub-pixels and depth sub-pixels integrated in a pixel array on the same image sensor are known.

### SUMMARY OF INVENTION

There is a need to improve existing devices for acquiring a 2D image and a depth image of a scene. It would be desirable to produce an image sensor integrating 2D image sub-pixels and depth sub-pixels in the same pixel array, in particular with the sensor having a higher efficiency for depth image acquisition than known sensors.

One object of one embodiment is to overcome some or all of the drawbacks of known devices for acquiring a 2D image and a depth image of a scene.

To this end, one embodiment provides an image sensor comprising a plurality of pixels formed in and on a semiconductor substrate, each pixel including:
at least one first photosensitive region formed in the semiconductor substrate, and adapted to collect light in a first range of wavelengths;
a second photosensitive region formed in the semiconductor substrate in line with said at least one first photosensitive region, and adapted to collect light in a second range of wavelengths, different from the first range of wavelengths;
at least one charge collection area disposed on the side of the substrate opposite to said at least one first photosensitive area;
at least one transfer region extending from said at least one first photosensitive area to said at least one charge collection area; and
at least one transfer gate extending vertically between said at least one transfer region and the second photosensitive area, and laterally bordering said at least one transfer region.

According to one embodiment, each pixel further includes a peripheral insulating trench extending vertically into the semiconductor substrate, from said side of the second photosensitive area, and laterally delimiting said at least one first photosensitive area and the second photosensitive area.

According to one embodiment, each transfer gate includes a first insulating trench extending into the semiconductor substrate from said side of the substrate opposite to said at least one first photosensitive area, and partially entering the thickness of said at least one first photosensitive area.

According to one embodiment, each charge collection area extends laterally between the peripheral insulating trench and the or one of the first insulating trenches.

According to one embodiment, each transfer gate is surrounded by a second insulating trench extending vertically into the substrate from said side of the substrate opposite to said at least one first photosensitive area.

According to one embodiment, each pixel further includes at least one further transfer gate extending laterally on said side of the substrate opposite to said at least one first photosensitive area and at least one further charge collection area.

According to one embodiment, each pixel includes four first photosensitive areas.

According to one embodiment, the first photosensitive areas are isolated from each other by a third insulating trench.

According to one embodiment, the second photosensitive area is on and in contact with the first photosensitive area.

According to one embodiment, the sensor further includes a control circuit configured to alternately apply, to said at least one transfer gate:
a first potential adapted to block a transfer of charges from said at least one first photosensitive area to said at least one charge collection area; and
a second potential, different from the first potential, adapted to allow a transfer of charges from said at least one first photosensitive area to said at least one charge collection area.

According to one embodiment, the first photosensitive areas of the pixels of the sensor are intended to capture a 2D image, and the second photosensitive areas of the pixels of the sensor are intended to capture a depth image.

### BRIEF DESCRIPTION OF DRAWINGS

The foregoing features and advantages, as well as others, will be described in detail in the following description of specific embodiments given by way of illustration and not limitation with reference to the accompanying drawings, in which:

FIG. 1 is a schematic, partial top view of an image sensor pixel according to one embodiment;

FIG. 2 is a cross-sectional view of the pixel shown in FIG. 1, along plane AA shown in FIG. 1;

FIG. 3 is a cross-sectional view of the pixel shown in FIG. 1, along plane BB shown in FIG. 1;

FIG. 4 is a schematic, partial top view of an image sensor pixel according to another embodiment;

FIG. 5 is a cross-sectional view of the pixel shown in FIG. 4, along plane AA shown in FIG. 4;

FIG. 6 is a cross-sectional view, along plane AA shown in FIG. 1, of a step in a method for manufacturing the pixel shown in FIG. 1;

FIG. 7 is a cross-sectional view, along plane AA shown in FIG. 1, of a step in the method for manufacturing the pixel shown in FIG. 1;

FIG. 8 is a cross-sectional view, along plane BB shown in FIG. 1, of a step in the method for manufacturing the pixel shown in FIG. 1;

FIG. 9 is a cross-sectional view, along plane AA shown in FIG. 1, of a step in the method for manufacturing the pixel shown in FIG. 1; and

FIG. 10 is a cross-sectional view, along plane BB shown in FIG. 1, of a step in the method for manufacturing the pixel shown in FIG. 1.

### DESCRIPTION OF EMBODIMENTS

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail. In particular, the pixel circuits (transistors and connections) have not been described in detail, as the embodiments and variants described are compatible with conventional pixel circuits. Furthermore, the sense circuits, or column decoders, the control circuits, or row decoders, and the applications in which image sensors can be provided have not been described in detail, the embodiments and variants described being compatible with the sense circuits and control circuits of conventional image sensors, as well as with conventional applications implementing image sensors.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

The “transmittance of a layer” refers to the ratio between the intensity of radiation leaving the layer and the intensity of radiation entering the layer. In the following description, a layer or film is said to be opaque to radiation when the transmittance of the radiation through the layer or film is less than 10%. In the following description, a layer or film is said to be transparent to radiation when the transmittance of the radiation through the layer or film is greater than 10%.

In the following description, “visible light” refers to electromagnetic radiation with a wavelength between 380 nm and 780 nm, and “infrared radiation” refers to electromagnetic radiation with a wavelength between 780 nm and 15 μm. Further, “near infrared radiation” refers more specifically to electromagnetic radiation with a wavelength between 780 nm and 1.7 μm.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

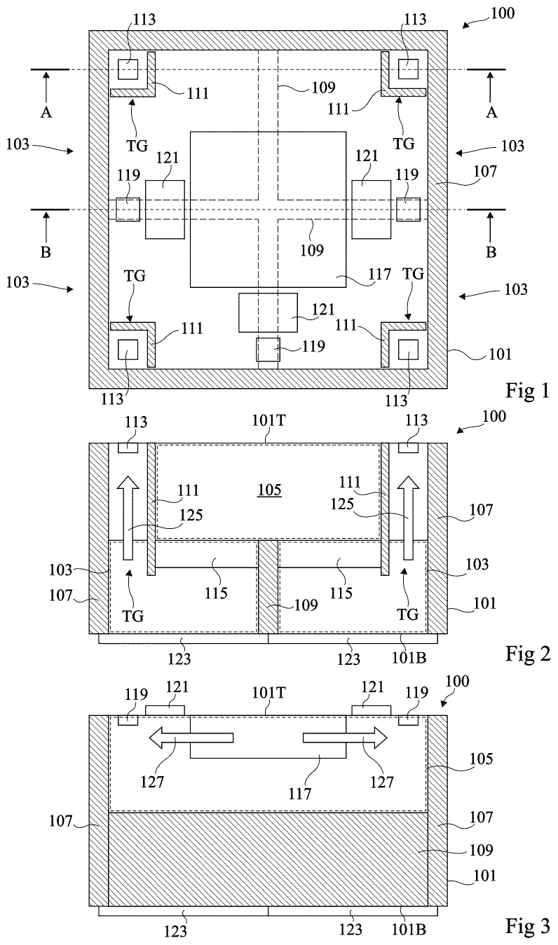

FIG. 1 is a schematic, partial top view of an image sensor pixel 100 according to one embodiment. FIGS. 2 and 3 are cross-sectional views, along planes AA and BB shown in FIG. 1, respectively, of the pixel 100 shown in FIG. 1.

In the example shown, the pixel 100 is formed in and on a semiconductor substrate 101, made of silicon for example. By way of example, substrate 101 has a thickness of between 5 and 20 μm.

In the example shown, the pixel 100 includes first photosensitive areas 103 formed in the semiconductor substrate 101. As shown in FIG. 2, each photosensitive area 103 extends vertically through the thickness of the semiconductor substrate 101 from a bottom face 101B of the substrate 101 up to a depth less than the thickness of the substrate 101. More precisely, in the illustrated example, the pixel 100 includes four first photosensitive areas 103. When viewed from above, each photosensitive area 103 has a substantially square periphery. In the example shown, the four photosensitive areas 103 are coplanar and arranged, when viewed from above, in a substantially square overall shape. The photosensitive areas 103 are formed, for example, in a region of the substrate 101 doped with a first type of conductivity, such as n-type.

In the example shown, the pixel 100 further includes a second photosensitive area 105 formed in the semiconductor substrate 101. The second photosensitive area 105 is located in line with the first photosensitive areas 103 (above the first photosensitive areas 103, in the orientation shown in FIGS. 2 and 3). As illustrated in FIGS. 2 and 3, the photosensitive area 105 extends vertically through the thickness of the semiconductor substrate 101 from a top face 101T of the substrate 101, opposite to the bottom face 101B. When viewed from above, photosensitive area 105 has a substantially square periphery. In this example, photosensitive area 105 has lateral dimensions substantially equal to those of the square formed by the four photosensitive areas 103. The photosensitive area 105 is formed, for example, in a region of the substrate 101 doped with a second conductivity type opposite to the first conductivity type, the p-type in this example. By way of example, in the region where the photosensitive area 105 is formed, the substrate 101 has a doping level of between 1×1010 and 1×1017 at./cm3. In this example, the second photosensitive area 105 is in contact, via its bottom face, with the top face of the underlying first photosensitive areas 103.

Each photosensitive area 103, 105, for example, is intended to collect photons during illumination phases of the image sensor to which the pixel 100 belongs, and to convert these photons into electron-hole pairs. In this example, the first photosensitive areas 103 are adapted to collect light in a first wavelength range, and the second photosensitive area 105 is adapted to collect light in a second wavelength range, different from the first wavelength range. The first photosensitive areas 103 are intended, for example, to capture 2D images, and the second photosensitive area 105 is intended, for example, to capture depth images. By way of example, the photosensitive areas 103 of the pixel 100 are adapted to capture visible light, for example blue light, and the photosensitive area 105 of the pixel 100 is adapted to capture infrared radiation, for example near infrared radiation.

In the example shown, where the first and second photosensitive areas are made of the same material, e.g. silicon, visible light and infrared radiation are predominantly absorbed at different depths in the substrate 101 from its bottom face 101B. In this example, the majority absorption depth of visible light is less than that of infrared radiation. By way of example, the second photosensitive area has a greater thickness than the first photosensitive areas, in order to optimize the absorption of infrared radiation in the second photosensitive area. Alternatively, the first photosensitive areas can be made of a first material, such as silicon, and the second photosensitive area can be made of a second material different from the first material, such as germanium or a silicon-germanium alloy. The first and second materials are then respectively adapted to absorb predominantly infrared and visible radiation.

In the example shown, the pixel 100 further includes a peripheral insulating trench 107, for example a capacitive insulating trench, laterally delimiting the second photosensitive area 105 and the arrangement formed by the first photosensitive areas 103. More specifically, in this example, the peripheral insulating trench 107 completely surrounds the photosensitive area 105 and, when viewed from above, has a substantially square contour.

The peripheral insulating trench 107 electrically isolates the photosensitive areas 103 and 105 of pixel 100 from the photosensitive areas of neighboring pixels, not shown in FIGS. 1 to 3. The peripheral insulating trench 107 is formed in the substrate 101. In the orientation shown in FIGS. 2 and 3, the peripheral insulating trench 107 extends vertically through the thickness of the substrate 101 from the top face 101T of the substrate 101 up to the bottom face 101B of the substrate 101. In other words, in this example, the peripheral insulating trench 107 extends vertically through the entire thickness of the substrate 101 and opens out on the side of the top 101T and bottom 101B faces of the substrate 101.

For example, the peripheral insulating trench 107 has a width of between 200 and 600 nm, and a depth of between 1 and 20 μm. In the example shown in FIGS. 2 and 3, the peripheral insulating trench 107 has a depth equal to the thickness of the substrate 101.

Although not shown in detail in FIGS. 1 to 3, the peripheral insulating trench 107 includes, for example, an electrically conductive region the sidewalls of which are coated with an electrically insulating layer. The electrically insulating layer electrically isolates the electrically conductive region of the trench 107 from the substrate 101. By way of example, the electrically conductive region of trench 107 is made of polycrystalline silicon, a metal, such as copper, or a metal alloy, and the electrically insulating layer of trench 107 is made of a dielectric material, such as silicon oxide. By way of example, the peripheral insulating trench 107 is a trench of the CDTI (Capacitive Deep Trench Isolation)-type.

In the example shown, the first photosensitive areas 103 of the pixel 100 are separated from each other by an insulating trench 109, for example a capacitive insulating trench, e.g. of the CDTI type. In this example, the pixel 100 more precisely comprises an insulating trench 109 having, when viewed from above, a general cross shape substantially centered with respect to the pixel 100. As illustrated in FIGS. 2 and 3, the insulating trench 109 extends vertically through the thickness of the semiconductor substrate 101 from the bottom face 101B of the substrate 101 up to the photosensitive area 105, without however opening out on the side of the top face 101T of the substrate 101, the insulating trench 109 having, for example, as illustrated in FIGS. 2 and 3, a height substantially equal to the thickness of the first photosensitive areas 103. In the example shown, each first photosensitive area 103 is thus bordered laterally by the peripheral insulating trench 107 and by the insulating trench 109. By way of example, trench 109 has a similar structure to trench 107. More specifically, trench 109 may, for example, have an electrically conductive region, e.g. a metal region, or a charged region, e.g. charged polycrystalline silicon, the sides of which are coated with an electrically insulating layer. Alternatively, trench 109 is a charged insulating trench, for example of the DTI (Deep Trench Isolation) type. In this case, trench 109 has for example no electrically conductive region.

In the example shown in FIGS. 1 to 3, pixel 100 further includes four vertical transfer gates TG, each comprising an insulating trench 111, for example a capacitive insulating trench. In this example, each insulating trench 111 is generally L-shaped when viewed from above. As illustrated in FIGS. 2 and 3, each insulating trench 111 extends vertically through the thickness of the semiconductor substrate 101 from the top face 101T of the substrate 101 up to one of the first photosensitive areas 103, and partially enters the photosensitive area 103 up to a depth less than that of the peripheral insulating trench 107. In other words, each insulating trench 111 is interrupted within the thickness of the substrate 101 and does not open out on the bottom face 101B side of the substrate 101. By way of example, each insulating trench 111 has a depth of between 3 and 18 μm.

In this example, the insulating trenches 111 are, when viewed from above, located at the four corners of the square formed by the peripheral insulating trench 107. More precisely, the insulating trenches 111 are arranged so as to delimit regions of the substrate 101 which, when viewed from above, have a substantially square shape. In the example shown in FIG. 1, parts of the substrate 101 are interposed between the ends of the L formed by each insulating trench 111 and the facing walls of the peripheral insulating trench 107.

Each insulating trench 111, for example, has a structure similar to that of the peripheral insulating trench 107. More specifically, although not shown in detail in FIGS. 1 to 3, each insulating trench 111 includes, for example, an electrically conductive region, for example made of polycrystalline silicon, a metal, for example copper, or a metal alloy. The electrically conductive region of each insulating trench 111 is, for example, of the same material as the electrically conductive region of the peripheral insulating trench 107. Further, each trench 111 includes, for example, an electrically insulating layer coating the side walls and bottom face of the electrically conductive region. The electrically insulating layer electrically isolates the electrically conductive region of trench 111 from the substrate 101. By way of example, the electrically insulating layer of each trench 111 is made of a dielectric material, e.g. silicon oxide. The electrically insulating layer of each insulating trench 111 is, for example, of the same material as the electrically insulating layer of the peripheral insulating trench 107.

The electrically conductive region of each insulating trench 111 is, for example, electrically isolated from the electrically conductive region of the peripheral insulating trench 107. This allows, for example, the electrically conductive region of each insulating trench 111 to be polarized independently of the electrically conductive region of the peripheral insulating trench 107.

In the example shown, the pixel 100 further includes charge collection areas 113 arranged on the side of the substrate opposite to the first photosensitive areas 103, i.e. on the side of the face 101T of the substrate. In the orientation shown in FIG. 2, the charge collection areas 113 extend vertically through the thickness of the substrate 101 from its top face 101T, up to a depth less than that of the insulating trenches 111. In this example, each charge collection area 113 is surrounded by one of the insulating trenches 111 and by the peripheral insulating trench 107. By way of example, each charge collection area 113 has a substantially square shape when viewed from above. Each charge collection area 113 is, for example, more heavily doped with the second conductivity type, in this example the p-type (p+), than the photosensitive area 105. By way of example, the substrate 101 has a doping level of between 1×1016 and 5×1020 at./cm3 at the point where each charge collection area 113 is formed.

In the example shown, each first photosensitive area 103 includes a region 115 doped with the second conductivity type, p-type in this example. The regions 115 are, for example, heavily doped with p-type (p+). In this example, the regions 115 extend vertically through the thickness of the substrate 101 from a face of the photosensitive areas 103 at the side of the photosensitive area 105 up to a depth less than the thickness of the photosensitive areas 103. Within each first photosensitive area 103, region 115 forms a photodiode with a portion of substrate 101 doped with the first conductivity type, n-type in this example. The region 115 further allows charge transfers from the photosensitive areas 103 to the photosensitive area 105 of the pixel 101 to be blocked. Alternatively, region 115 can be omitted, for example in a case where the vertical transfer gate TG is close to the insulating trench 109.

In the example shown, the photosensitive area 105 includes a region 117 doped with the first type of conductivity, the n-type in this example. In this example, region 117 extends vertically through the thickness of substrate 101 from its top surface 101T up to a depth less than the thickness of second photosensitive area 105. In the example shown in FIG. 1, region 117 has a substantially square shape, and is substantially centered with respect to the peripheral insulating trench 107 of pixel 100. Within the second photosensitive area 105, region 117 forms, together with a part of substrate 101 doped with the second conductivity type, p-type in this example, a photodiode.

In the example shown, the pixel 100 also includes charge collection areas 119 arranged on the side of the substrate opposite to the first photosensitive areas 103, i.e. on the side of the top face 101T of the substrate. In the orientation shown in FIG. 2, the charge collection areas 119 extend vertically through the thickness of the substrate 101 from its top surface 101T up to a depth less than the thickness of the region 117. Specifically, in this example, pixel 100 has three charge-collection areas 119, each located between one side of region 117 and one side of peripheral insulating trench 107.

In the example shown, pixel 100 further includes transfer gates 121, for example planar transfer gates, located on and in contact with the top face 101T of substrate 101. Each transfer gate 121 is located, for example, in line with a portion of the substrate 101 between region 117 and one of the charge collection areas 119. Alternatively, different numbers of transfer gates 121 and charge collection areas 119 could be provided than those shown, for example four charge collection areas 119 associated respectively with four transfer gates 121.

In this example, the photosensitive areas 103 and 105 are intended to be illuminated from the bottom face 101B of the substrate 101. As illustrated in FIGS. 2 and 3, the pixel 100 may further comprise color filters 123 located on and in contact with the bottom face 101B of the substrate 101. In the example shown, each color filter 123 is located in line with one of the first photosensitive areas 103. Each color filter 123 is, for example, transparent to only part of the visible spectrum, e.g. blue light, and to at least part of the infrared spectrum, e.g. near infrared radiation. Although not shown in FIGS. 1 to 3, the pixel 100 may further include one or more passivation layers, for example interposed between the bottom face 101B of the substrate 101 and the color filters 123, and other optical elements such as one or more microlenses.

Although not illustrated, at least one conductive pad may be located on and in contact with the electrically conductive region of the peripheral insulating trench 107. This conductive pad allows the electrically conductive region of trench 107 to be polarized. By way of example, the electrically conductive region of the peripheral insulating trench 107 is brought to a fixed potential, for example a negative potential, for example equal to about-2 V. This tends to cause an accumulation of holes along the side walls of the peripheral insulating trench 107. In particular, this accumulation of holes allows holes photogenerated in the photosensitive area 105 to be prevented from being trapped at the interface between the substrate 101 and the peripheral insulating trench 107, and further a potential suitable for operation of the photodiode of each of the 2D image pixels to be provided.

Further, although not shown in FIGS. 1 to 3, a further conductive pad may be provided, located on and in contact with the top surface 101T of substrate 101, for example in the vicinity of one of the charge collection areas 119, and a heavily doped region of the second conductivity type (p+ region, in this example) extending beneath the top surface 101T of substrate 101 in line with the conductive pad. The heavily doped region of the second conductivity type is, for example, subjected to a substantially zero potential by the conductive pad. This allows the holes accumulating along the side walls of the peripheral insulating trench 107 to be provided.

The pixel 100 may further include at least one other conductive pad located on and in contact with the electrically conductive region of each insulating trench 111. These conductive pads are intended, for example, to polarize the electrically conductive regions of the trenches 111.

During a phase of exposure of the pixel 100, for example, electron-hole pairs are created within each photosensitive area 103. During this phase, the electrically conductive region of each insulating trench 111 is brought to a fixed potential, for example a negative potential, e.g. equal to about-1.5 V, by a control circuit (not shown). During the sensor exposure phase, the application of this potential to the electrically conductive region of each trench 111 allows a potential barrier to be formed in a transfer region located inside each vertical transfer gate TG, between the photosensitive area 103 and the collection area 113. In the example shown, the transfer region is bordered by the inner side walls of the peripheral insulating trench 107 and the insulating trench 111, and extends vertically, through the thickness of the substrate 101, beneath the collection area 113.

The presence of the potential barrier in the transfer region allows, during the exposure phase, a transfer of photogenerated electrons from the photosensitive area 103 to the collection area 113 to be blocked. This potential barrier results from the presence, along the side walls of the insulating trenches 107 and 111, of a hole-attracting inversion layer, in this example.

In a read phase subsequent to the exposure phase, the electrically conductive region of each insulating trench 111, for example, is brought to a potential higher than the potential applied during the exposure phase, e.g. a positive potential, e.g. equal to around 0.5 V, by the control circuit (not shown). Applying this potential to the electrically conductive region of each trench 111 allows the potential barrier in the transfer region between the photosensitive areas 103 and the charge collection areas 113 to be lowered, or even eliminated. The disappearance of the potential barrier allows, during the read phase, photogenerated electrons to be transferred 125 from the photosensitive areas 103 to the collection areas 113. By way of example, the charge collection areas 113 are each brought to a fixed potential, for example a positive potential, e.g. equal to around 2.5 V, during the exposure and read phases. This allows photogenerated electrons to be attracted towards the areas 113 during the read phase.

Further, during an exposure phase of the pixel 100, electron-hole pairs are created within the photosensitive area 105, for example. During this phase, the electrons photogenerated in area 105 are for example transferred, in turn, towards the various charge collection areas 119 of pixel 100. To this end, one of the planar transfer gates 121 is, for example, brought to a first potential allowing photogenerated electrons to be transferred from area 105 to one of the areas 119, while the other gates 121 are brought to a second potential allowing electron transfer to the other areas 119 to be blocked. Then, another gate 121 is brought to the first potential, the other gates then being brought to the second potential, and so on until all the gates 121 have been successively brought to the first potential. During the same exposure phase, the gates 121 of pixel 100 are opened sequentially, for example by applying control signals that are out of phase with one another to these gates, in order to allow photogenerated electrons to be transferred from photosensitive area 105 to a single collection area 119 simultaneously. This sequence of opening the transfer gates 121 is repeated many times during the exposure phase, for example. This allows for example time-of-flight distance measurements, for example, indirect time-of-flight (iToF) measurements to be implement by pixel 100. By way of example, the opening frequency of each transfer gate 121 is between 10 and 300 MHz, and each exposure phase includes a number of opening periods of the transfer gate 121 between ten thousand and one million.

During the exposure phase, the gates 121 brought to the second potential force a potential barrier in a transfer region located between the region 117 of the photosensitive area 105 and the collection areas 119 associated with these gates. This potential barrier results from the presence of a hole-attracting inversion layer beneath the planar transfer gates 121 brought at the second potential, in this example. Conversely, the gate 121 at the first potential lowers, or even eliminates, the potential barrier in the transfer region between region 117 and the charge collection area 119 associated with this gate. By way of example, the first potential is positive, e.g. equal to around 0.5 V, and the second potential is lower than the first potential, e.g. negative, e.g. equal to around-2 V.

By way of example, the charge collection areas 119 are each brought to a fixed starting potential, for example a positive potential, e.g. equal to around 2.5 V, prior to the exposure phase. This allows photogenerated electrons to be attracted towards the areas 119 during the exposure phase. During the exposure phase, the potential of each area 119 decreases according to a number of electrons transferred from the photosensitive area 105 to this area 119. At the end of the exposure phase, the potential of areas 119 is measured, for example, to determine the total amount of charge that has been integrated by each area 119 during the exposure phase. Once the measurement is complete, the charge collection areas are for example brought back to their starting potential before the next exposure phase.

In the example shown where the pixel 100 includes three planar transfer gates 121 respectively associated with three charge collection areas 119, one of the planar transfer gates 121 and the charge collection area 119 associated with this gate can act as an antiblooming device. More specifically, one of the planar transfer gates can be controlled so as to allow excess photogenerated charges to be discharged when pixel 100 is in the reading phase.

One advantage of the pixel 100 described above in relation to FIGS. 1 to 3 lays in that the first semiconductor photosensitive areas 103 and the second semiconductor photosensitive area 105 are superimposed without an intermediate layer, the second photosensitive area 105 being on and in contact with the first photosensitive areas. In particular, this allows losses during light transmission from the first photosensitive areas 103 to the second photosensitive area 105 to be limited, for example compared with a pixel in which the photosensitive areas 103 and 105 would each have been previously produced on different substrates, these substrates then being transferred one onto the other. In particular, the absence of interconnection structures between the first photosensitive areas and the second photosensitive area, formed for example in metallization levels separated from one another by insulating layers, allows transmission losses to be limited.

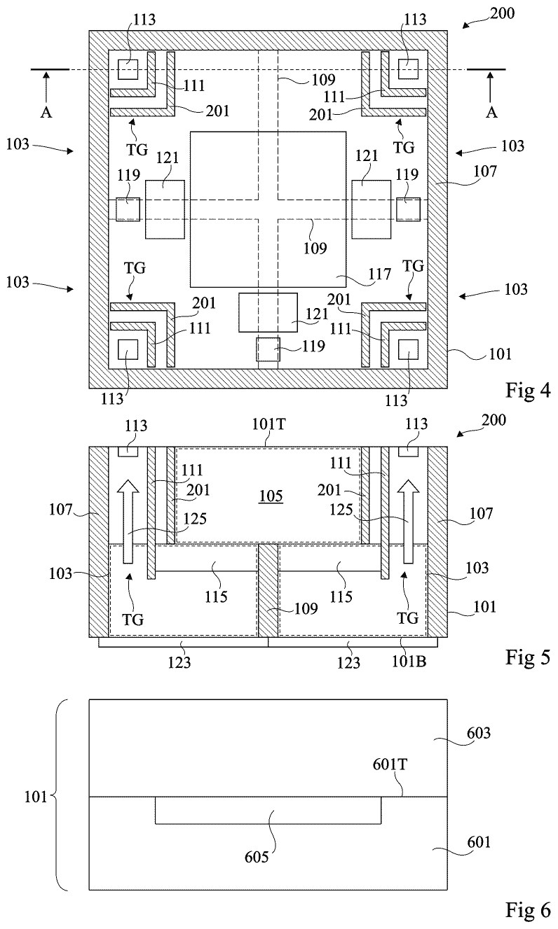

FIG. 4 is a schematic, partial top view of a pixel 200 of an image sensor according to another embodiment. FIG. 5 is a cross-sectional view of the pixel 200 shown in FIG. 4, along plane AA shown in FIG. 4.

Pixel 200 shown in FIGS. 4 and 5 has elements in common with pixel 100 shown in FIGS. 1 to 3. These common elements will not be described again in detail hereinafter. The pixel 200 shown in FIGS. 4 and 5 differs from the pixel 100 shown in FIGS. 1 to 3 in that the pixel 200 further includes insulating trenches 201, for example capacitive insulating trenches, surrounding the insulating trenches 111.

In this example, pixel 100 more precisely includes four insulating trenches 201, each of which, when viewed from above, is generally L-shaped. As illustrated in FIG. 5, each isolation trench 201 extends vertically through the thickness of the semiconductor substrate 101 from the top face 101T of the substrate 101 up to a depth substantially equal to the thickness of the second photosensitive area 105. In this example, the insulating trenches 201 do not penetrate inside the first photosensitive areas 103. By way of example, each insulating trench 201 has a depth of between 3 and 18 μm.

In this example, the insulating trenches 201 are, when viewed from above, located at the four corners of the square formed by the peripheral insulating trench 107. More precisely, the insulating trenches 201 are arranged so as to delimit regions of the substrate 101 which, when viewed from above, is substantially square-shaped. In the example shown in FIG. 4, parts of the substrate 101 are interposed between the ends of the L formed by each insulating trench 201 and the facing walls of the peripheral insulating trench 107.

Each insulating trench 201, for example, has a structure similar to that of the peripheral insulating trench 107. More specifically, although not shown in detail in FIGS. 4 and 5, each insulating trench 201 includes, for example, an electrically conductive region, for example made of polycrystalline silicon, a metal, for example copper, or a metal alloy. The electrically conductive region of each insulating trench 201 is, for example, made of the same material as the electrically conductive region of the peripheral insulating trench 107. Further, each trench 201 includes, for example, an electrically insulating layer coating the side walls and bottom face of the electrically conductive region. The electrically insulating layer electrically isolates the electrically conductive region of trench 201 from the substrate 101. By way of example, the electrically insulating layer of each trench 201 is made of a dielectric material, such as silicon oxide. The electrically insulating layer of each insulating trench 201 is, for example, made of the same material as the electrically insulating layer of the peripheral insulating trench 107.

The electrically conductive region of each insulating trench 201 is, for example, electrically isolated from the electrically conductive region of the peripheral insulating trench 107. This allows, for example, the electrically conductive region of each insulating trench 201 to be polarized independently of the electrically conductive region of the peripheral insulating trench 107. Alternatively, the electrically conductive regions of the insulating trenches 201 may be in contact with the electrically conductive region of the peripheral insulating trench 107.

During the exposure and read phases of the pixel 200, the electrically conductive region of each insulating trench 201 is brought to a fixed potential, for example a negative potential, for example equal to around-2 V. This tends to cause an accumulation of holes along the side walls of the insulating trenches 201. In particular, this accumulation of holes allows photogenerated holes in the second photosensitive area 105 to be prevented from being trapped at the interface between the substrate 101 and the insulating trenches 111 during the read phase of the first photosensitive areas 103. In the case of pixel 200, regions 115 can also be omitted thanks to the presence of insulating trenches 201.

An advantage of the pixel 200 described above in relation to FIGS. 4 and 5 is that the insulating trenches 201 allows the vertical TG gates associated with the first photosensitive areas 103 to be controlled, while preventing photogenerated charges from being trapped at the interface between the substrate 101 and the insulating trenches 111. This advantageously allows the pixel 200 to acquire 2D and depth images at a same time.

FIGS. 6 to 10 are schematic, partial cross-sectional views illustrating successive steps in an example method for manufacturing pixel 100 according to one embodiment.

FIG. 6 is a cross-sectional view, along the AA plane shown in FIG. 1, illustrating a structure obtained after an ion implantation step, on the side of a top face 601T of a semiconductor substrate 601, and an epitaxy step of a layer 603 coating the top face 601T of the semiconductor substrate 601.

The semiconductor substrate 601 is, for example, a wafer or a piece of wafer, only part of which is shown in FIG. 6. By way of example, substrate 601 is made of a semiconductor material, such as silicon. For example, the substrate 601 is doped with the first conductivity type, n-type in this example.

In the example shown, during the ion implantation step, a well 605 is formed, extending vertically through the thickness of the substrate 601 from its top surface 601T up to a depth less than the thickness of the substrate 601. By way of example, in a case where the semiconductor substrate 601 is made of silicon, well 605 is implemented via implantation with boron ions (B3+) so as to achieve p-type doping.

Layer 603 is then formed by epitaxial growing on and in contact with the top face 601T of semiconductor substrate 601. Layer 603 is doped with the second conductivity type, p-type in this example. By way of example, layer 603 is made of the same material as semiconductor substrate 601.

For example, semiconductor substrate 601 and layer 603 together form the semiconductor substrate 100 of the pixel 100 shown in FIGS. 1 to 3.

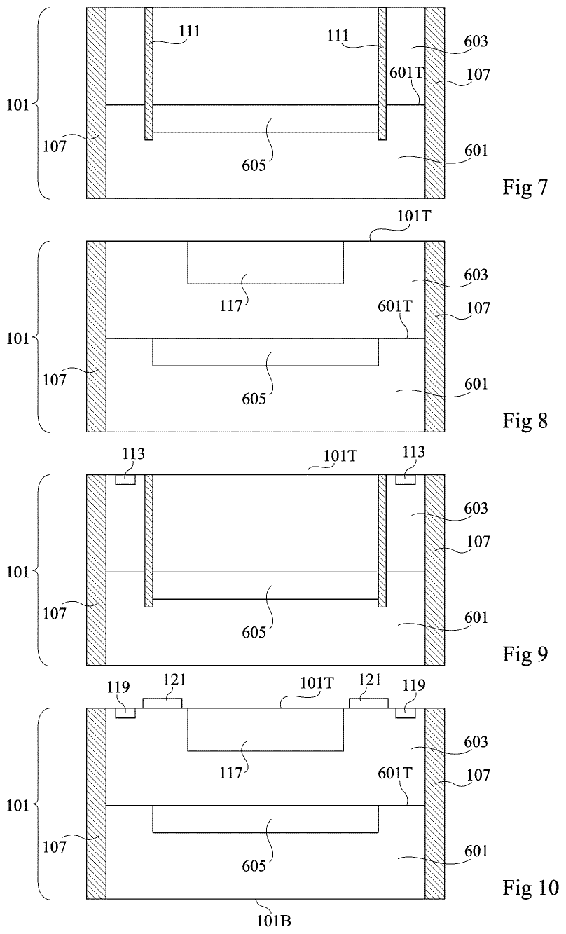

FIG. 7 is a cross-sectional view, along plane AA shown in FIG. 1, illustrating a subsequent step for manufacturing the peripheral insulating trench 107 and the insulating trenches 111. In the example shown in FIG. 7, the insulating trenches 111 border the well 605.

FIG. 8 is a cross-sectional view along plane BB shown in FIG. 1, illustrating a subsequent ion implantation step at the side of the top face 101T of the substrate 101.

Particularly, in the example shown, during the ion implantation step, a well is formed corresponding to the region 117 extending vertically through the thickness of the substrate 101 from its top face 101T. More precisely, in this example, region 117 extends vertically from face 101T up to a depth less than the thickness of layer 603.

FIG. 9 is a cross-sectional view, according to plane AA shown in FIG. 1, of a subsequent step for implementing the charge collection areas 113 and 119 (not visible in FIG. 9).

Charge collection areas 113 and 119 are implemented, for example, by ion implantation located on the side of the top face 101T of substrate 101.

FIG. 10 is a cross-sectional view, along plane BB shown in FIG. 1, of a subsequent step for implementing the transfer gates 121.

For example, gates 121 are obtained at the end of a step of depositing a layer coating the top face 101T of substrate 101, followed by steps of photolithography and etching.

Various embodiments and variants have been described. Those skilled in the art will understand that certain features of these embodiments can be combined and other variants will readily occur to those skilled in the art. In particular, those skilled in the art will be able, from the present disclosure, to adapt the embodiments described to pixels each including a different number of first photosensitive areas from that shown in FIGS. 1 to 5. Particularly, those skilled in the art will be able to implement pixels each including a second photosensitive area superimposed on a single first photosensitive area. In this case, the isolating trench 109 can be omitted, and a single vertical transfer gate can be provided. Those skilled in the art will further be able to implement pixels each including a second photosensitive area superimposed on two first photosensitive areas, the two first photosensitive areas being separated in this case by a single isolating trench, for example.

Furthermore, the embodiments are not limited to the above example geometries. In particular, pixels, photosensitive areas and isolating trenches may have geometries different from those shown in the present description.

Further, although have been above described embodiments in which the pixel includes three planar gates 121 associated with three charge collection areas 119, those skilled in the art will be able to provide a number of gates 121 and areas 119 depending on the application, for example one gate 121 and one area 119 intended for acquiring a depth image, and one gate 121 and one area 119 intended for antiblooming.

Finally, the practical implementation of the embodiments and variants described herein is within the capabilities of those skilled in the art based on the functional description provided hereinabove. In particular, those skilled in the art will be able to adapt the method described in relation to FIGS. 6 to 10 to implement the pixel 200 of FIGS. 4 and 5 from the above indications.

1. An image sensor comprising a plurality of pixels formed in and on a semiconductor substrate, each pixel including:
at least one first photosensitive region formed in the semiconductor substrate, and adapted to collect light in a first range of wavelengths;
a second photosensitive region formed in the semiconductor substrate in line with said at least one first photosensitive region, and adapted to collect light in a second range of wavelengths, different from the first range of wavelengths;
at least one charge collection area disposed on the of the substrate opposite to said at least one first photosensitive area;
a peripheral isolating trench extending vertically into the semiconductor substrate, from said side of the second photosensitive area, and laterally delimiting said at least one first photosensitive area and the second photosensitive area;
at least one transfer region extending from said at least one first photosensitive area to said at least one charge collection area; and
at least one transfer gate extending vertically between said at least one transfer region and the second photosensitive area, and laterally bordering said at least one transfer region,
wherein each transfer gate is bordered by intern sidewalls of the peripheral isolating trench and transfer gate.

2. The sensor according to claim 1, wherein each transfer gate further includes a first insulating trench extending into the semiconductor substrate from said side of the substrate opposite to said at least one first photosensitive area, and partially entering the thickness of said at least one first photosensitive area.

3. The sensor according to claim 2, wherein each charge collection area extends laterally between the peripheral insulating trench and the or one of the first insulating trenches.

4. The sensor according to claim 1, wherein each transfer gate is surrounded by a second insulating trench extending vertically into the substrate from said side of the substrate opposite to said at least one first photosensitive area.

5. The sensor according to of claim 1, wherein each pixel further includes at least one further transfer gate extending laterally on said side of the substrate opposite to said at least one first photosensitive area and at least one further charge collection area.

6. The sensor according to claim 1, wherein each pixel includes four first photosensitive areas.

7. The sensor according to claim 6, wherein first photosensitive areas are isolated from each other by a third insulating trench.

8. The sensor according to claim 1, wherein the second photosensitive area is on and in contact with the first photosensitive area.

9. The sensor according to claim 1, further including a control circuit configured to alternately apply, to said at least one transfer gate:
a first potential adapted to block a transfer of charges from said at least one first photosensitive area to said at least one charge collection area; and
a second potential, different from the first potential, adapted to allow a transfer of charges from said at least one first photosensitive area to said at least one charge collection area.

10. The sensor according to claim 1, wherein the first photosensitive areas of the sensor pixels are intended to capture a 2D image, and the second photosensitive areas of the sensor pixels are intended to capture a depth image.
